(19) United States
(12) Patent Application Publication
(10) Pub. No.: US 2017/0347485 A1
(43) Pub. Date: Nov. 30, 2017

(54) Power Conversion Device

(71) Applicant: Hitachi Automotive Systems, Ltd., Hitachinaka-shi, Ibaraki (JP)

(72) Inventors: Akira ISHII, Hitachinaka (JP); Hiroyuki YAMAI, Hitachinaka (JP); Takeshi KATO, Hitachinaka (JP)

(21) Appl. No.: 15/535,733

(22) PCT Filed: Jan. 8, 2016
(86) PCT No.: PCT/JP2016/050412

§ 371 Date: Jun. 14, 2017

(30) Foreign Application Priority Data
Jan. 26, 2015 (JP) 2015-011928

(51) Int. Cl. H05K 7/20; H02M 7/00

(52) U.S. Cl. CPC H05K 7/2089; H02M 7/003

(57) ABSTRACT

It is an object of the present invention to further lower the temperature of a bus bar penetrating through a current sensor. A power conversion device according to the present invention includes: a bus bar for transferring current; a current sensor having a core part for forming a throughhole for penetrating the bus bar therein; a base part arranged inside the throughhole of the core part to oppose the bus bar; and a heat transfer member, wherein the base part has an extended part protruding from the throughhole, and the extended part is extended to the heat transfer member and thermally contacts with the heat transfer member.

### TECHNICAL FIELD

The present invention relates to a power conversion device, and particularly to a power conversion device for converting direct current used for vehicles into alternating current or converting alternating current into direct current.

### BACKGROUND ART

In recent years, voltage/current values of a power conversion device are increasing yearly in hybrid automobiles or electric automobiles, and the power conversion device is mounted on a vehicle and is also required to downsize. In JP 2012-58199 A (PTL 1), a device is directed to reduce heat generation by securing a maximum cross-section area of a bus bar in a limited space, but is not enough to process the amount of heat generated when large current flows.

Further, in JP 2012-163454 A (PTL 2), a device is directed to reduce thermal effects by putting a Hall element away from a heat-generated bus bar, but it is assumed that a generated electromagnetic field is disturbed due to distortion of a cross-section shape of the bus bar.

### CITATION LIST

### Patent Literature

PTL 1: JP 2012-58199 A

PTL 2: JP 2012-163454 A

### SUMMARY OF INVENTION

### Technical Problem

It is an object of the present invention to further lower the temperature of a bus bar penetrating through a current sensor.

### Solution to Problem

In order to solve the problem, a power conversion device according to the present invention includes: a bus bar for transferring current; a current sensor having a core part for forming a throughhole for penetrating the bus bar therein; a base part arranged inside the throughhole of the core part to oppose the bus bar; and a heat transfer member, wherein the base part has an extended part protruding from the throughhole, and the extended part is extended to the heat transfer member and thermally contacts with the heat transfer member.

### Advantageous Effects of Invention

According to the present invention, it is possible to enhance heat radiation efficiency of a bus bar penetrating through a current sensor.

### BRIEF DESCRIPTION OF DRAWINGS

FIG. 1 is a perspective view of an entire power conversion device 1 according to the present embodiment from which a lid (not illustrated) is removed.

FIG. 2 is an exploded perspective view of the power conversion device 1.

FIG. 3 is a perspective view of an entire main circuit assembly 2.

FIG. 4 is an exploded perspective view of the main circuit assembly 2.

FIG. 5 illustrates a cross section of the main circuit assembly 2 viewed in the arrow direction on plane A in FIG. 3.

FIG. 6 is an enlarged view of the main circuit assembly 2 at part C in FIG. 5.

FIG. 7 is an enlarged view of the main circuit assembly 2 in the arrow direction in FIG. 6.

### DESCRIPTION OF EMBODIMENTS

An embodiment of the present invention will be described below with reference to the drawings. Specific examples of the contents of the present invention will be explained in the following description, but the present invention is not limited to the description, and various changes and modifications can be made by those skilled in the art within the scope of the technical spirit disclosed in the specification. The same functions are denoted with the same reference numerals and a repeated description thereof may be omitted throughout the drawings for describing the present invention.

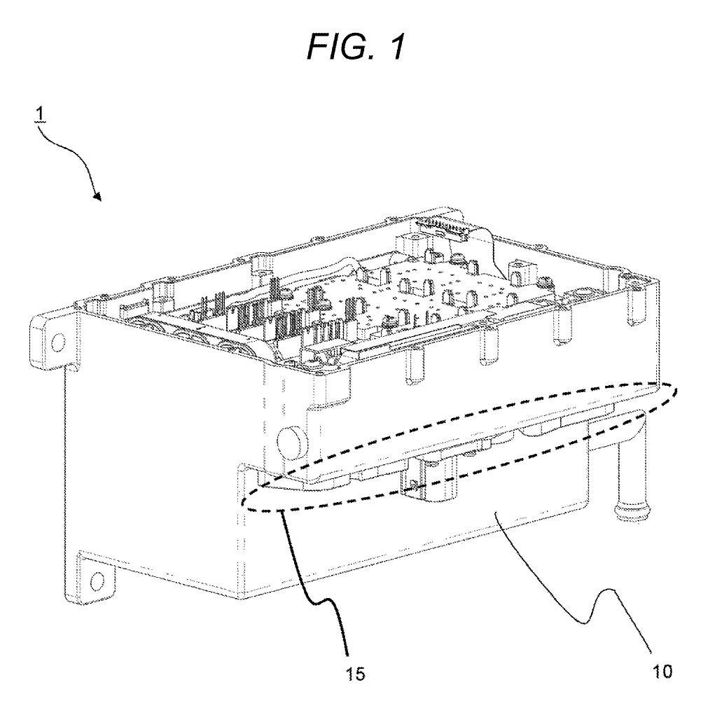

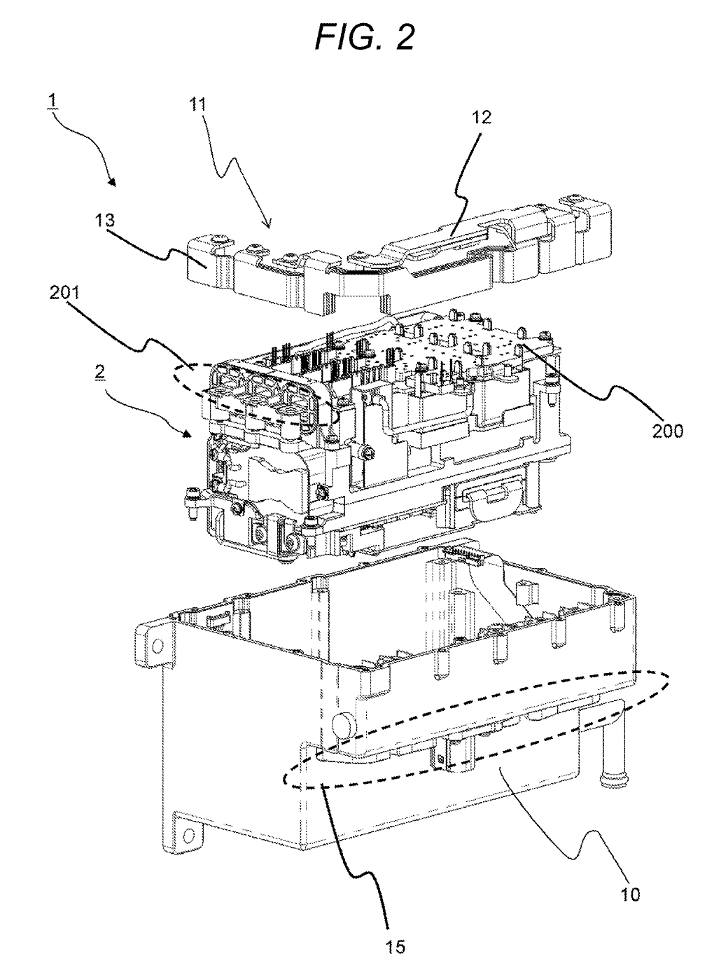

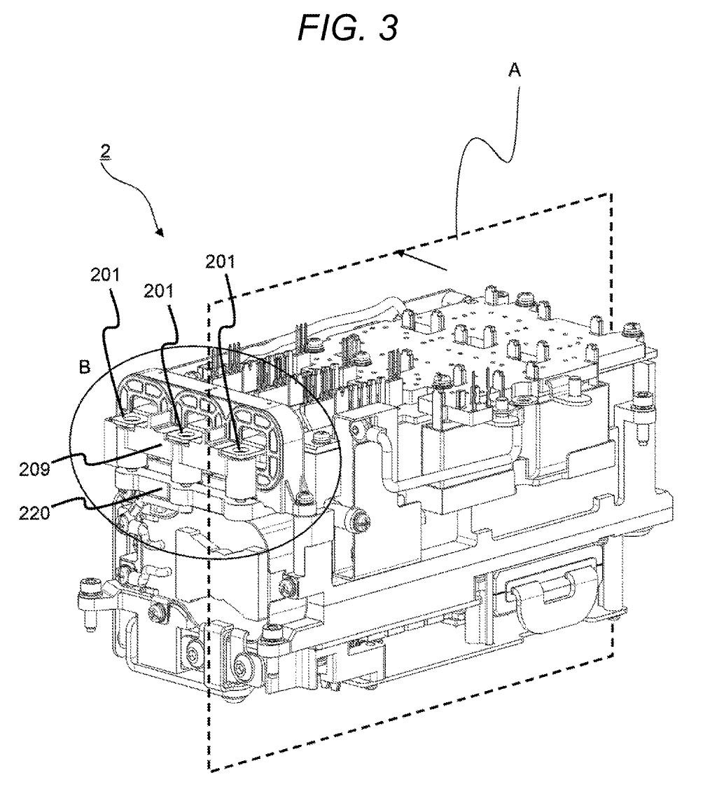

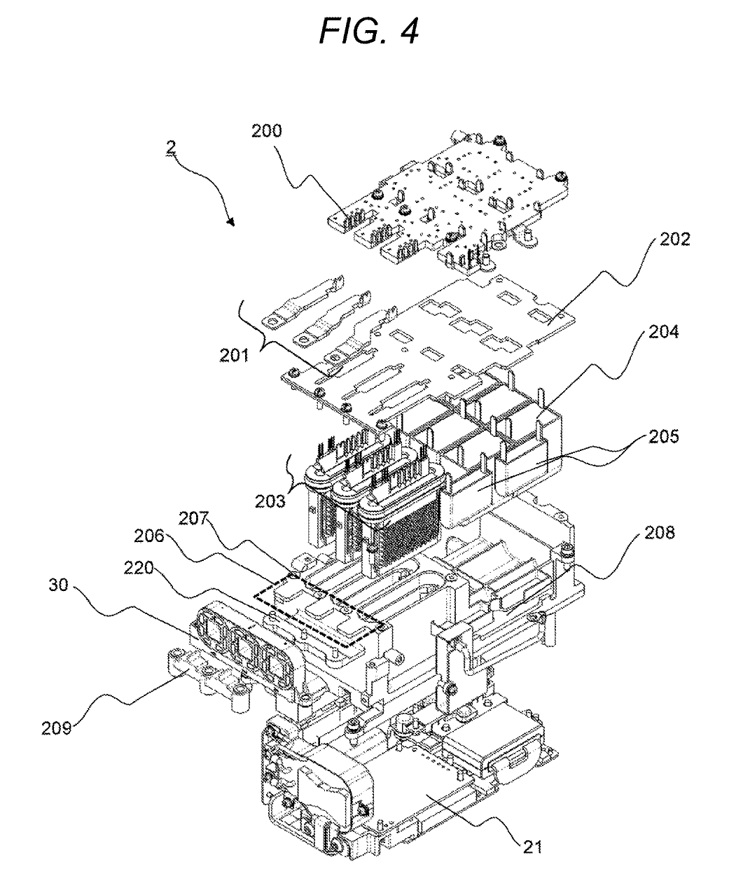

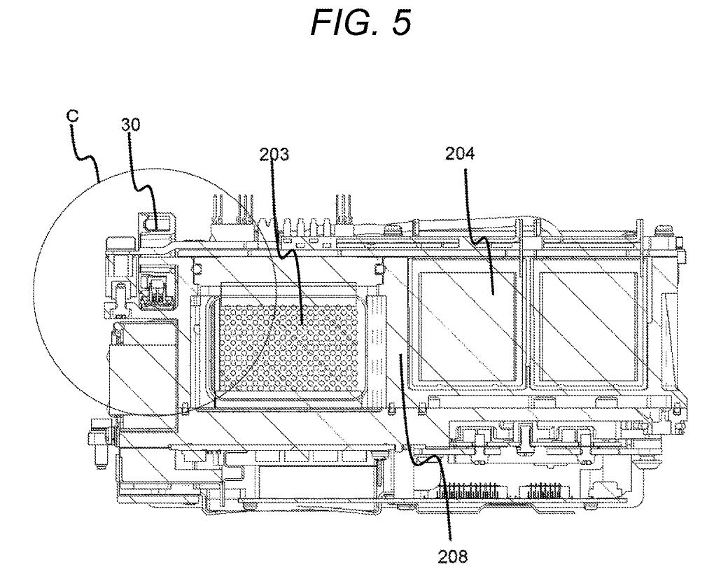

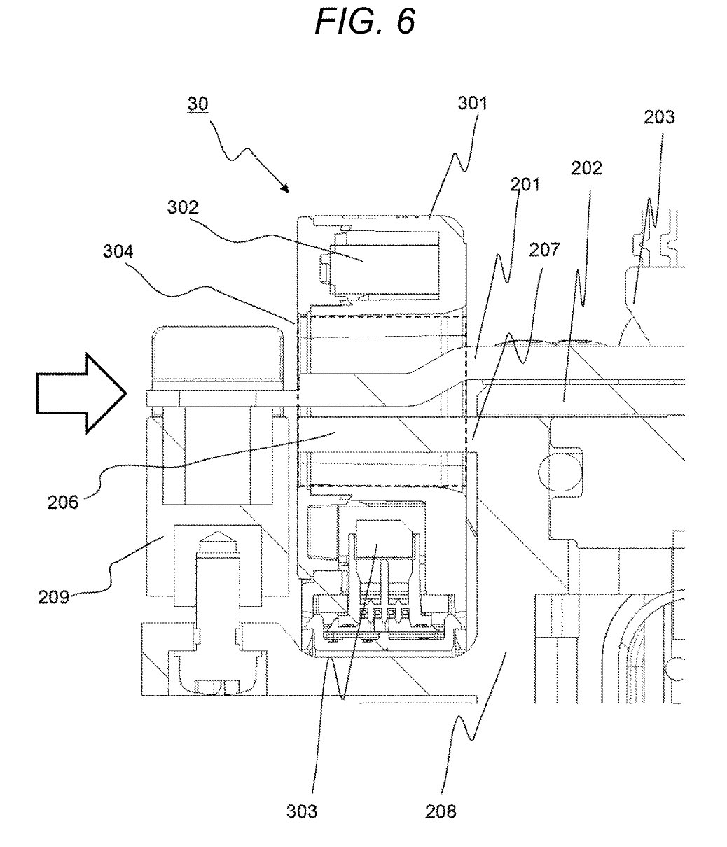

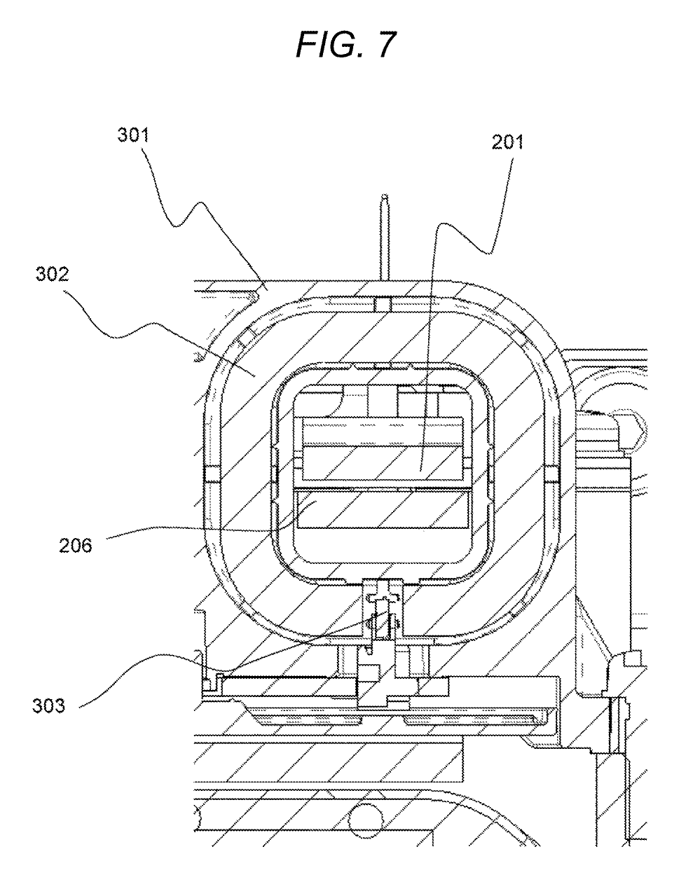

FIG. 1 is a perspective view of an entire power conversion device 1 according to the present embodiment from which a lid (not illustrated) is removed. FIG. 2 is an exploded perspective view of the power conversion device 1. FIG. 3 is a perspective view of an entire main circuit assembly 2. FIG. 4 is an exploded perspective view of the main circuit assembly 2. FIG. 5 illustrates a cross section of the main circuit assembly 2 viewed in the arrow direction on plane A in FIG. 3. FIG. 6 is an enlarged view of the main circuit assembly 2 at part C in FIG. 5. FIG. 7 is an enlarged view of the main circuit assembly 2 in the arrow direction in FIG. 6.

As illustrated in FIG. 2, a casing 10 houses the main circuit assembly 2 and a relay bus bar 11 therein. The casing 10 is made of a metal such as aluminum die-cast in order to restrict noises and to enhance cooling performance. The main circuit assembly 2 is connected to an external interface 15 of the casing 10 via the relay bus bar 11. The relay bus bar 11 is configured of a DC relay bus bar 12 for relaying a mold bus bar 200 described below and the external interface 15, and an AC relay bus bar 13 for relaying an AC bus bar 201 described below and the external interface 15.

A power semiconductor module 203 illustrated in FIG. 4 has an inverter circuit for converting DC power into AC power. Three power semiconductor modules 203 are provided, and output U-phase alternating current, V-phase alternating current and W-phase alternating current, respectively.

Capacitor modules 204 illustrated in FIG. 4 smooth DC power supplied to the power semiconductor modules 203. Noise cancellation capacitors 205 cancels noise in direct current mixed in the DC relay bus bar 12. The connection part between the noise cancellation capacitors 205 and the mold bus bar 200 is arranged closer to the DC relay bus bar 12 than the connection part between the capacitor modules 204 and the mold bus bar 200 in order to enhance the noise cancellation function.

The mold bus bar 200 comprises a metallic bus bar for electrically connecting the power semiconductor modules 203 and the capacitor modules 204, and a mold material covering the bus bar.

A flow channel shaper 208 illustrated in FIG. 4 forms a space for housing the power semiconductor modules 203 therein, a space for housing the capacitor modules 204 therein, and a flow channel for flowing refrigerant. The flow channel of the flow channel shaper 208 is formed to mainly cool the power semiconductor modules 203, and may be formed below the capacitor modules 204 in order to cool the capacitor modules 204.

As illustrated in FIG. 4, according to the present embodiment, the main circuit assembly 2 comprises a DCDC converter module 21 for increasing or decreasing a voltage of DC power. The DCDC converter module 21 is fixed on the flow channel shaper 208 different from the face where the power semiconductor modules 203 and the capacitor module 204 are arranged, and thus the DCDC converter module 21 can sufficiently secure a heat radiation face.

A base plate 202 illustrated in FIG. 4 is fixed on the flow channel shaper 208 to press the power semiconductor modules 203 onto the flow channel shaper 208.

A current sensor 30 illustrated in FIG. 4 detects alternating current output from the power semiconductor modules 203. As illustrated in FIG. 6, the current sensor 30 comprises a core part 302, a Hall element 303 for detecting alternating current, and a current sensor case 301 for housing the core part 302 and the Hall element 303 therein. The current sensor case 301 is made of insulative resin. The core part 302 is a magnetic body made of ferrite or silicon steel, and is circularly formed to surround a space as throughhole 304. The Hall element 303 is arranged in a gap of the core part 302, and detects a magnetic flux changing depending on current passing through the throughhole 304.

The AC bus bar 201 illustrated in FIG. 4 and FIG. 6 is connected to the power semiconductor modules 203, is extended to the current sensor 30, and further penetrates through the core part 302.

As illustrated in FIG. 3 and FIG. 4, a terminal board 209 is arranged opposite to the power semiconductor modules 203 via the current sensor 30. Part of the AC bus bar 201 penetrating through the core part 302 is sandwiched between the terminal board 209 and the AC relay bus bar 13, and thus the AC bus bar 201 is connected to the AC relay bus bar 13 and the AC bus bar 201 is supported on the terminal board 209. Further, the terminal board 209 is a resin-molded component, and forms a female screw for fixing the AC bus bar 201.

A protrusion 220 illustrated in FIG. 3 and FIG. 4 supports the terminal board 209. The protrusion 220 is connected to the flow channel shaper 208 to be thermally connected to the flow channel shaper 208. Thereby, the AC bus bar 201 is cooled by the refrigerant flowing through the flow channel shaper 208 via the terminal board 209 and the protrusion 220.

A temperature environment in which the power conversion device 1 used for a drive motor in a hybrid automobile or electric automobile is so severe, and the power conversion device 1 needs to be further downsized. The AC bus bar 201 for transferring current flowing through the drive motor largely generates heat. On the other hand, the core part 302 through which the AC bus bar 201 penetrates, the Hall element 303, and the current sensor case 301 are lower in heat resistance than other components in the power conversion device 1. Thus, the cross-section area of the AC bus bar 201 is increased in order to restrict heat generation in the AC bus bar 201. However, the power conversion device 1 needs to be downsized, and an increase in the cross-section area of the AC bus bar 201 is limited.

For example, the heatproof temperature of the Hall element 303 is about 125° C., the heatproof temperature of the resin-made current sensor case 301 is 120° C., the atmosphere temperature at which the power conversion device 1 is arranged is 105° C., the flow channel shaper 208 having a cooling structure generally has a water cooling structure, and the temperature of the refrigerant thereof is 85° C. The temperature in the internal space of the power conversion device 1 or around the AC bus bar 201 is increased due to the atmosphere temperature (105° C.) at which the power conversion device 1 is arranged. Heat of the AC bus bar 201 is transferred to the current sensor 30 and the current sensor 30 is increased in temperature only by radiating heat of the AC bus bar 201 into the internal space of the power conversion device 1. Therefore, a “temperature gradient” between the internal space of the power conversion device 1 and the current sensor 30 is reduced and heat radiation of the current sensor 30 is not enough.

According to the present embodiment, alternating current flowing through the AC bus bar 201 is so high as about 500 A, and the temperature of the AC bus bar 201 penetrating through the throughhole 304 of the current sensor 30 increases up to about 160° C.

Thus, as illustrated in FIG. 6 and FIG. 7, a base part 206 is arranged inside the throughhole 304 of the core part 302 in the current sensor 30 to oppose the AC bus bar 201. Further, the base part 206 has an extended part 207 protruding from the throughhole 304. Then, the extended part 207 is extended to the flow channel shaper 208 and thermally contacts with the flow channel shaper 208.

Thereby, heat of the AC bus bar 201 is transferred to the base part 206, and is further transferred to the flow channel shaper 208 via the extended part 207. Reliability for heat of the current sensor 30 can be enhanced. As another effect, the cross-section area of the AC bus bar 201 can be reduced, and thus the size of the core part 302 in the current sensor 30 can be reduced, thereby downsizing the power conversion device 1.

The AC bus bar 201 is used according to the present embodiment, but the present invention can be applied to bus bars for transferring current with large heat generation.

Further, the base part 206 may be integral with the current sensor 30 thereby to form a current sensor module body of the current sensor 30 and the base part 206. In this case, the base part 206 in the current sensor module body is thermally connected to the extended part 207 protruding from the flow channel shaper 208.

Further, the flow channel shaper 208 functions as heat transfer member according to the present embodiment, but the casing 10 may function as heat transfer member. In this case, the casing 10 comprises the extended part 207 and the base part 206.

The base part 206, the extended part 207, and the flow channel shaper 208 are integrally formed in order to reduce heat resistance in the heat transfer path according to the present embodiment, but the respective components may be configured as separate members and may be mechanically connected to be thermally connected with each other.

A gap is provided between the inner periphery of the core part 302 and the AC bus bar 201 in order to secure an insulative distance between the core part 302 in the current sensor 30 and the AC bus bar 201. Thus, the current sensor case 301 is made of resin and the core part 302 is embedded by transfer mold or the like thereby to contain the core part 302 therein. Thereby, the gap between the inner periphery of the core part 302 and the AC bus bar 201 can be downsized, and the size of the core part 302 can be reduced. However, the core part 302 is sensitive to thermal effects by the AC bus bar 201.

Therefore, the base part 206 opposing the AC bus bar 201 is embedded in the current sensor case 301 and the extended part 207 connected to the base part 206 thermally contacts with the flow channel shaper 208 thereby to lower the temperature of the AC bus bar 201. Further, the base part 206 is embedded in the current sensor 30 by transfer mold or the like, which leads to a reduction in assembling steps.

### REFERENCE SIGNS LIST

1 . . . power conversion device, 2 . . . main circuit assembly, 10 . . . casing, 11 . . . relay bus bar, 12 . . . DC relay bus bar, 13 . . . AC relay bus bar, 15 . . . external interface, 21 . . . DCDC converter module, 200 . . . mold bus bar, 201 . . . AC bus bar, 202 . . . base plate, 203 . . . power semiconductor module, 204 . . . capacitor module, 205 . . . noise cancellation capacitor, 206 . . . base part, 207 . . . extended part, 208 . . . cooling shaper, 209 . . . terminal board, 220 . . . protrusion, 30 . . . current sensor, 301 . . . current sensor case, 302 . . . core part, 303 . . . Hall element, 304 . . . throughhole

1. A power conversion device comprising:
a bus bar for transferring current;
a current sensor having a core part for forming a throughhole for penetrating the bus bar therein;
a base part arranged inside the throughhole of the core part to oppose the bus bar; and
a heat transfer member,
wherein the base part has an extended part protruding from the throughhole, and
the extended part is extended to the heat transfer member and thermally contacts with the heat transfer member.

2. The power conversion device according to claim 1,
wherein the base part, the extended part, and the heat transfer member are integrally formed.

3. The power conversion device according to claim 1 or 2, comprising:
a power semiconductor module for converting direct current into alternating current,
wherein the heat transfer member is a flow channel shaper which forms a flow channel for flowing therein refrigerant for cooling the power semiconductor module.

4. The power conversion device according to claim 1,
wherein the current sensor has a resin case for embedding the core part and the base part therein.
